(19) United States
(12) Patent Application Publication
(10) Pub. No.: US 2012/0256305 A1
(43) Pub. Date: Oct. 11, 2012

(54) Integrated Circuit Package Security Fence

(75) Inventors: Matthew Kaufmann, Morgan Hill, CA (US); Mark Buer, Payson, AZ (US); Reza Sharifi, Irvine, CA (US)

(73) Assignee: Broadcom Corporation, Irvine, CA (US)

(21) Appl. No.: 13/250,624

(22) Filed: Sep. 30, 2011

Related U.S. Application Data
(63) Continuation-in-part of application No. 12/330,336, filed on Dec. 8, 2008.
(60) Provisional application No. 61/012,013, filed on Dec. 6, 2007.

(51) Int. Cl. H01L 23/52

(52) U.S. Cl. 257/659; 257/E23.141

(57) ABSTRACT

Embodiments of an integrated circuit package security fence are provided. The integrated circuit package includes a substrate, a die, and a security fence coupled to the substrate such that the die is located between the security fence and the substrate. The security fence includes a first signal net having a plurality of bonding wires and a second signal net having a second plurality of bonding wires. The bonding wires of the first signal net and second signal net are arranged in a pattern to overlap the top surface of die. The die may include tamper detection logic to detect attempt to access the die through the security fence.

### CROSS-REFERENCE TO RELATED APPLICATIONS

This application is a continuation-in-part of U.S. Non-provisional application Ser. No. 12/330,336 filed Dec. 8, 2008, which claims the benefit of U.S. Provisional Application No. 61/012,013 filed Dec. 6, 2007, both of which are incorporated herein by reference in their entirety.

### FIELD OF THE INVENTION

This invention generally relates to the security of integrated circuit devices and specifically to physical security of integrated circuit devices.

### BACKGROUND OF THE INVENTION

Certain types of devices are targets for sophisticated attacks. For example, chips storing cryptographic keys or other secure data or chips performing secure transactions (e.g., credit card transactions) are particularly attractive to attackers. One style of physical attacks, referred to as an enclosure attack, involves penetrating the device enclosure to physically access the device. In these physical attacks, the package is opened and any encapsulating material is removed or etched away. The attacker then accesses the internals of the chip or device using a probe. The attacker can then observe and/or manipulate the internal chip signals.

What is therefore needed is package level security combining logical protection, embedded physical security measures, and active tamper detection for critical data and signals.

### BRIEF DESCRIPTION OF THE FIGURES

The accompanying drawings, which are included to provide a further understanding of the invention and are incorporated in and constitute a part of this specification, illustrate embodiments of the invention and together with the description serve to explain the principles of the invention. In the drawings:

FIG. 1 depicts an exemplary conventional technique for package protection.

FIG. 2 depicts a cross-section of an exemplary package having bond wire package security, according to embodiments of the present invention.

FIG. 3 depicts a top view of a portion of an exemplary package, according to embodiments of the present invention.

FIG. 4 depicts a top view of adjacent stagger-pads, according to embodiments of the present invention.

FIG. 5 depicts a top view of a portion of an exemplary package having multiple tamper detection circuits, according to embodiments of the present invention.

FIG. 6 depicts an exemplary die having a detection mesh grid above a portion of the die, according to embodiments of the present invention.

FIG. 7 depicts a cross section of the secure area of a die, according to embodiments of the present invention.

FIG. 8 depicts an exemplary protective mesh pattern, according to embodiments of the present invention.

FIG. 9 depicts another exemplary protective mesh pattern, according to embodiments of the present invention.

FIG. 10 depicts a single layer protective mesh, according to embodiments of the present invention.

FIGS. 11 and 12 depict stacked die embodiments having mechanical only security protection.

FIGS. 13 and 14 depict stacked die protection embodiments, according to embodiments of the invention.

FIGS. 15 and 16 depict exemplary package-on-package approaches, according to embodiments of the present invention.

FIG. 17 depicts a three-dimensional top view of an exemplary package having a wire-frame security fence, according to embodiments of the present invention.

FIG. 18 depicts a cross-section of the exemplary package, according to embodiments of the present invention.

FIG. 19 depicts a top view of an exemplary security fence having in-line contacts, according to embodiments of the present invention.

FIG. 20 depicts a top view of an exemplary security fence having offset substrate contacts, according to embodiments of the present invention.

FIG. 21 depicts a top view of an exemplary security fence having coated or insulated bonding wires, according to embodiments of the present invention.

The present invention will now be described with reference to the accompanying drawings. In the drawings, like reference numbers may indicate identical or functionally similar elements

### DETAILED DESCRIPTION OF THE INVENTION

### 1.0 Overview

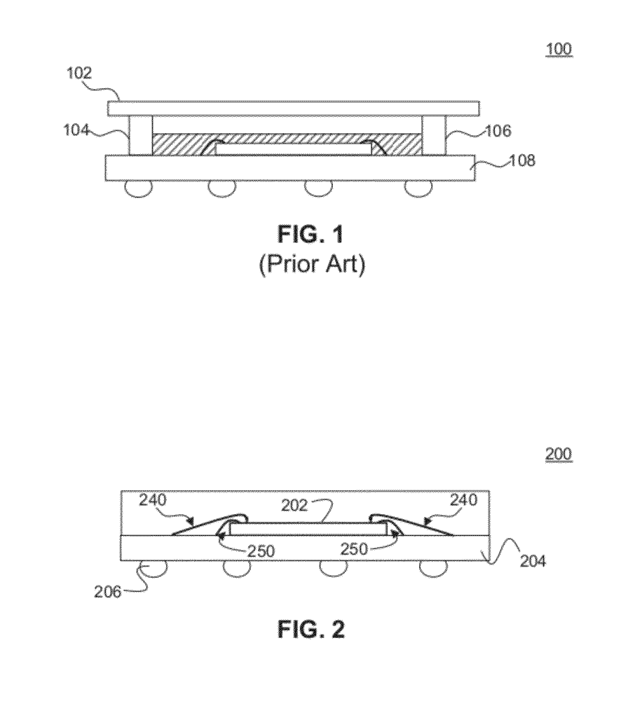

Critical components of a chip or device may be attacked from the top, sides, or bottom of its package. Conventional techniques to protect against these physical attacks, particularly those that do not provide logical protection of critical signals, construct a box around one or more chips. FIG. 1 depicts such an exemplary conventional technique for package protection. As depicted in FIG. 1, package 100 has a top circuit board 102, a first side circuit board 104 mounted at a 90 degree angle to circuit board 102, a second side circuit board 106 also mounted at a 90 degree angle to circuit board 102, and a bottom circuit board 108. A grid mesh is run through the circuit board enclosure. The enclosure acts to surround all the protected components (referred to as a “bag of chips”). This technique is difficult and expensive to manufacture.

Embodiments of the present invention described herein provide protection against attacks from the top, bottom, and/or side of the package. The bond wire protection embodiments described in Section 2 provide protection against and detection of attacks from the side of a package. The top protection embodiments (e.g., the stacked die and package-on-package) embodiments described in Section 4 below provide protection against and detection of attacks to the top of the package. The package-on-package embodiments described in Section 4 also provide physical protection against side attacks. Protection from bottom attacks may be provided via a board level mesh located in the substrate onto which the die is attached. A board level mesh may be provided using normal manufacturing techniques.

### 2.0 Bond Wire Protection

FIG. 2 depicts a cross-section of an exemplary package 200 having bond wire package security, according to embodiments of the present invention. Bond wire package security effectively creates a wire cage or grid of protection bond wires surrounding bond wires carrying sensitive chip signals. This cage of protection bond wires increases the difficulty of attaching a probe to the protected signal without detection.

Package 200 includes one or more integrated circuit (IC) dies 202 mounted on a substrate 204. In an embodiment, die 202 is an integrated security processor having an embedded system on chip processor and multiple peripheral devices. For example, the die may include sensitive input/output devices such as a magnetic strip reader, smartcard input/output, credit card reader, secure keypad, and/or touch screen. In an embodiment, the package substrate is a multi-layer board (e.g., 4-layer) and is used to route wire bonded signals to package balls 206.

In an embodiment, package 200 uses staggered pads in the I/O pad ring of the device. Pads for sensitive (or protected) signals (also referred to as “signal pads”) are placed on stagger-out pads (not shown). Stagger-out pads are on the farthest edge of the die. The protective bond mesh is implemented on stagger-in pads adjacent to the stagger-out pads. Stagger-in pads (not shown) are located behind the stagger-out bond pads and stagger-out (or “signal”) bond wires 250. The stagger-in bond wires (also referred to as “protection bond wires”) 240 are shaped so that they are vertically higher than the stagger-out bond wires. The protection bond wires therefore provide both vertical and horizontal protection of the stagger-out (sensitive signal) pads and bond wires 250. These sensitive signals are routed into the substrate before leaving the protective cage created by the protection wire bonds. As illustrated in FIG. 2, the design creates a cage of protection bond wires that surround and protect the sensitive signals.

The stagger-in protective pads (not shown) are constructed using a wire pad. The wire pad has no connection to the substrate or power planes of adjacent pads. The protective pads are only connected to isolated metal and isolated vias on the die. In an embodiment, the protection bond wires 240 are connected to form one or more protection circuits. A tamper signal is driven through each protection circuit to a detection circuit. For additional security, the driving pad(s) of the protection circuit may be driven from a protected security area of die 202 (such as described in Section 3.0 below). The detection circuit may be configured to detect a cut or short in the protection circuit. A detection circuit may also be configured to detect changes to other characteristics of the protection circuit such as capacitance or resistance changes.

Signals that leave the chip (via signal bond wires 250) may be logically protected using encryption and authentication techniques. Package 200 may also include integrated physical protection including frequency monitoring, voltage monitoring, temperature sensors, and a sensor mesh which protects the chip in certain sensitive areas.

As would be appreciated by persons of skill in the art, solder balls 206 are arranged in a pattern having a plurality of rows. In embodiments, security sensitive signals are placed at least two rows deep from the outside of the ball array. Less sensitive signals may be ideally placed at least one row deep from the outside of the package.

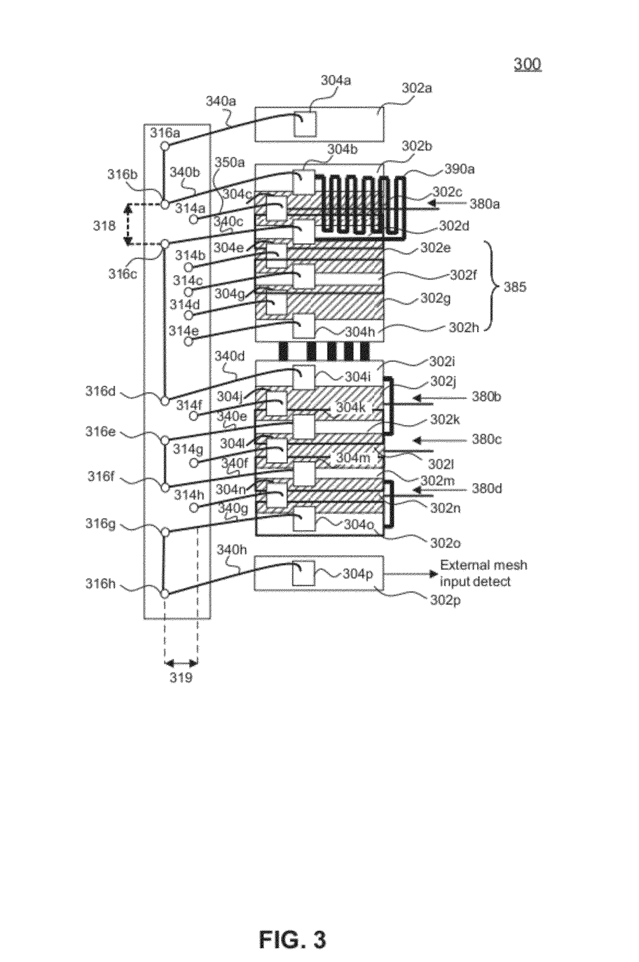

FIG. 3 depicts a top view of a portion of an exemplary package 300, according to embodiments of the present invention. Package 300 includes a plurality of pads 302a-p on a die (e.g., die 202 of FIG. 2). In an embodiment, pads 302 are positioned in a ring configuration (note that only a portion of the ring is depicted in FIG. 3). A pad 302 typically includes a pad contact 304. A set of pads 302 are used for wire bond protection (referred to as “protection pads”). The remaining pads 302 (shaded in FIG. 3) may be used for chip functions. For example, pads 302c, e, g, j, l, and n are chip function (stagger-out) pads and the remaining pads are protection (stagger-in) pads.

Although depicted as stagger-in pads, the mesh connection pads may be optionally stagger-in or stagger-out. A staggered configuration of pads allows for a higher density of pins which in turn allows the protection bond wires to be placed closer to one another, increasing the physical protection of the surrounded signal bond wire. In addition or alternatively, mesh connection pads may be in-line bond pads. Additionally, as depicted in FIG. 3, pads may be optionally overlapped.

FIG. 3 also depicts a portion of the package substrate that provides routing for the package. In an embodiment, routing is provided by a small printed circuit board (PCB) on the substrate. As illustrated in FIG. 3, the package substrate includes a set of outer contacts 316a-h and a set of inner contacts 314a-h. A pad landing 304 on the die may be coupled to a substrate contact via a wire bond. Substrate contacts are typically connected to solder balls 206 (shown in FIG. 2).

Protection wires 340a-n are typically bonded to the set of outer contacts 316. A bond wire carrying a physically protected signal, such as signal 380a, typically has a protection bond wire on each side. The effective vertical mesh spacing 318 between the outer substrate contacts for these protection wires is determined by the minimum spacing between protective (stagger-in) pads and a signal (stagger-out) pad. In the example shown in FIG. 3, a first physically protected signal 380a is routed from pad contact 304c to substrate inner contact 314a via signal bond wire 350a. To access substrate inner contact 314a, an attacker must fit a probe between protection wire bonds 340b and 340c. Therefore, the smaller the vertical mesh spacing the closer the protection wire bonds can be, resulting in greater physical protection for signal 380a. Vertical mesh spacing can also be decreased by increasing the horizontal spacing 319 between the substrate outer contacts 316 and the substrate inner contacts 314.

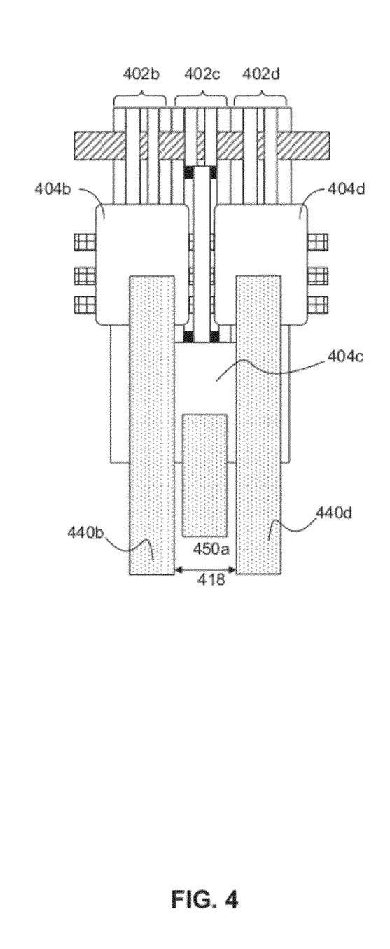

FIG. 4 depicts a top view of adjacent stagger-pads, according to embodiments of the present invention. Stagger-pad 402c is a sensitive signal (stagger-out) pad and receives a protected signal (e.g., signal 380a). Stagger-pads 402b and 402d are protection (stagger-in) pads. In the exemplary embodiment depicted in FIG. 4, stagger-pads 402b-d are not overlapped. Protection bond wires 440b and 440d are vertically higher than signal bond wire 450a. Pad landing 404b is coupled to protection bond wire 440b and pad landing 404d is coupled to protection bond wire 440d. In an embodiment, stagger-pads 402 are 30 μm wide and the protective and signal bond wires are 0.9 mils thick, creating an effective bond wire spacing 418 of 37.14 μm between the two protective bond wires. The horizontal spacing in this embodiment is only 7.14 μm.

As depicted in FIG. 3, protective (stagger-in) bond wires (e.g., bond wires 340b and 340c) protect a signal bond wire (e.g., signal bond wire 350a), the signal pad landing (e.g., 304c), and signal trace for the sensitive signal (stagger-out) pad. Additionally, the circuit connections between protective (stagger-in) pads on the die are connected to cover the signal trace of the stagger-out pad. In an embodiment, the connection may be patterned (e.g., in a zig zag) such as connection 390a. The use of a pattern trace allows additional physical protection of sensitive signal traces on the die.

In the exemplary package 300, a set of signals 380a-d have been designated for physical protection. Another set of signals 385 have been designated as not requiring additional physical protection. These signals may be protected by logical security and/or may have been deemed to not require additional physical security. As shown in FIG. 3, a protection circuit is created around one or more of the physically protected signals 380a-d. The protection circuit of FIG. 3 forms a zig zag pattern when viewed from the top.

In the protection circuit illustrated in FIG. 3, the driver (e.g., an external mesh driving circuit) is coupled to driving pad 302a. An exemplary mesh driving circuit is described in U.S. patent application Ser. No. 12/210,013, entitled “Mesh Grid Protection,” which is incorporated herein by reference in its entirety. Driving pad 302a may be driven from an external mesh driving circuit located in a security area on the die. Driving pad 302a is always active regardless of the state of the signals to be protected (powered or un-powered).

The driving pad 302a may be routed as a wire only connection between driving pad 302a and detection pad 302p. The wire is created using a bond wire to connect driving pad 302a (via pad landing 304a) to substrate contact 316a. Substrate contact 316a is connected to substrate 316b via a connection in the package substrate. A protection wire bond connects substrate contact 316b to protective pad 302b on the die. In an embodiment, pad 302b is an analog pad not tied to the substrate. The use of an analog pad in the protection circuit enables two different voltage levels to be used. Using this configuration, the protection/tamper detection circuit can remain active when the rest of the chip is powered off.

The pad landing 304b is connected to pad landing 304d using a metal connection (e.g., connected trace) on the die. As discussed above, this metal connection provides additional physical security for the signal trace carrying protected signal 380a. Signal pad 302c, between protective pads 302b and d, receives physically protected signal 380a. A bond wire connects protection pad 302d to substrate contact 316c which is connected to substrate contact 316d. Thus, the protection circuit effectively bypasses the unprotected signals 385. A wire bond connects substrate contact 316d to protection pad 302i which is connected to protection pad 302k using a metal connection which is then wire bonded off die to substrate contact 316e. The signal bond wire carrying physically protected signal 380b is surrounded by protection bond wires 340d and 340 e. This zig zag pattern continues until the last substrate outer contact 316h is bonded to detection pad 302p, creating the tamper detection circuit. The signal from the detection pad 304p is routed to an external detection circuit. An exemplary external detection circuit is described in U.S. patent application Ser. No. 12/210,013. In an embodiment, the zig zag mesh pattern is extended to cover the entire die.

A pad ring, a portion of which is depicted in FIG. 3, may have one or more gaps. The gap may serve to isolate a pad or set of pads. For example, no connectivity is provided between pad 302a and pad 302b over the pad gap. In this embodiment, pad 302a may be on a different power plane than pad 302b. Alternatively, connectivity may be provided across the gap such as is shown in the gap between pads 302h and 302i.

FIG. 3 depicts a single protection circuit for multiple physically protected signals. As would be appreciated by persons of skill in the art, multiple protection circuits may be used on a chip. For example, a user may want tamper detection around each sensitive signal. This configuration would allow the detection of an attacker attempting to access one device/function (e.g., a magnetic stripe reader) versus another device/function (e.g., secure key pad). Note that in alternate embodiments, the chip may have only a single protection circuit for the entire chip.

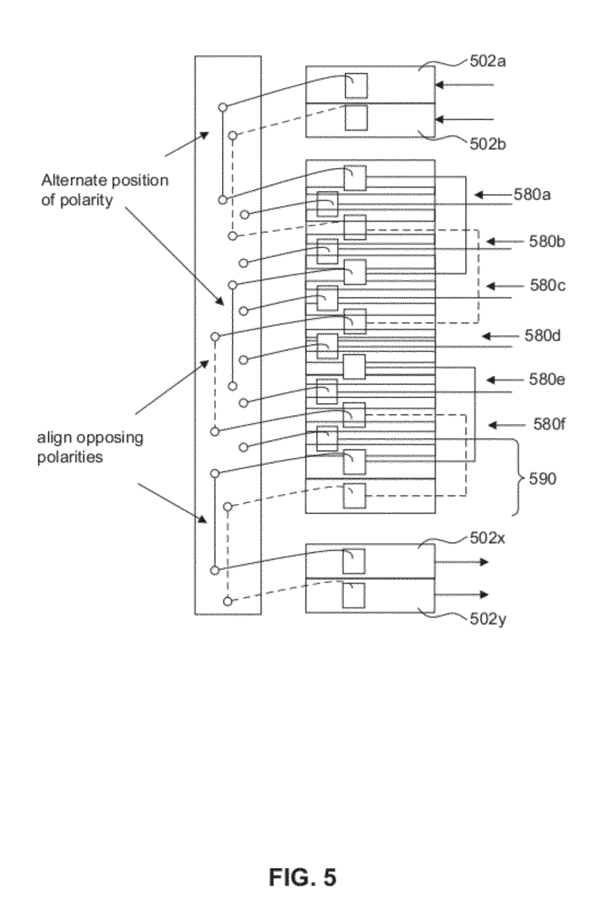

FIG. 5 depicts a top view of a portion of an exemplary package 500 having multiple tamper detection circuits, according to embodiments of the present invention. FIG. 5 specifically illustrates a view of connections between protective pads using two different polarity drivers. Connections having a first polarity are depicted as a solid line. Connections having the second polarity are depicted as a dashed line.

Package 500 includes two driving pads 502a, b (one for each polarity) and two detection pads 502x, y (one for each polarity). The detection circuits are configured to provide bond wire protection for sensitive signals 580a-f.

Because there are two separate tamper detection circuits (complete wires), an even number of on/off pads 590 are needed around the protected signal areas as shown in FIG. 5. In an embodiment, the final pads around a signal area may be routed back off the die to prevent a long signal trace from one protected pad area to the next.

Additionally, the two tamper detection circuit routes on the package may be alternated from being on the inside to the outside for connection to the next bond wire. This configuration prevents an attacker from shorting the signal at the package substrate layer. The metal connections on the die may similarly be alternated. The opposing tamper detection circuit polarities may further be aligned in the horizontal plane of the die and package to make bypass of the signals difficult.

### 3.0 Die Mesh Protection

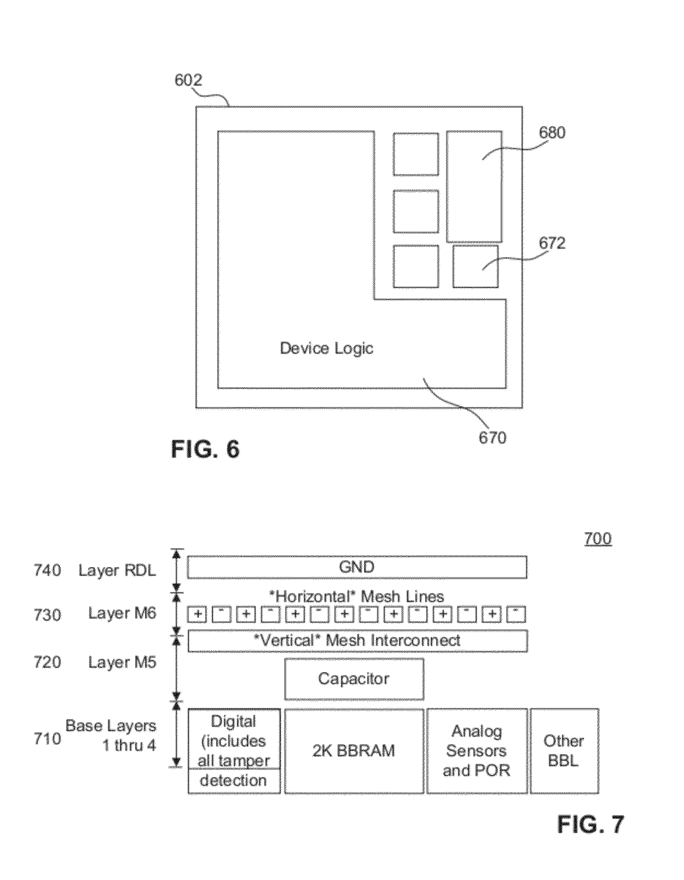

A die, such as die 202 depicted in FIG. 2, may also include a variety of internal mesh protections. FIG. 6 depicts an exemplary die 602 having a detection mesh grid above a portion of the die, according to embodiments of the present invention. Die 602 includes device logic 670, optional scratch battery backed RAM (BBRAM) 672, and a mesh grid 680 positioned into the corner of die 602. The mesh grid 680 covers a secure area of the die. The mesh grid provides at least a dual layer detection grid. The corner position is organized to make it more difficult for an attacker to etch back the package without destroying the bond wires for the power supply to the BBRAM. Additionally, positioning away from the dynamic logic of the device provides thermal isolation if a temperature monitor is included in the secure area of the die. As would be appreciated by persons of skill in the art, mesh grid 680 (and its associated secure area) may be located anywhere on the die.

Die 602 may also include a single or dual layer metal mesh above the active die area. The additional metal layer(s) may be driven by tamper detection signals from tamper logic located in the secure area of the die.

FIG. 7 depicts a cross section of the secure area 700 of a die, according to embodiments of the present invention. Secure area 700 includes an RDL layer 740, a M6 layer 730, an M5 layer 720, and base layers 710. Secure area 700 is protected by a metal layer 6 (M6) 730 grid, where connections to the grid are made in layer M5 720. Grid connections are always under the protective grid. RDL layer 740 provides a ground plane above the active grid of layer M6 730. The ground plane provides a physical blind as well as a short path to ground that can be detected with the M6 layer grid.

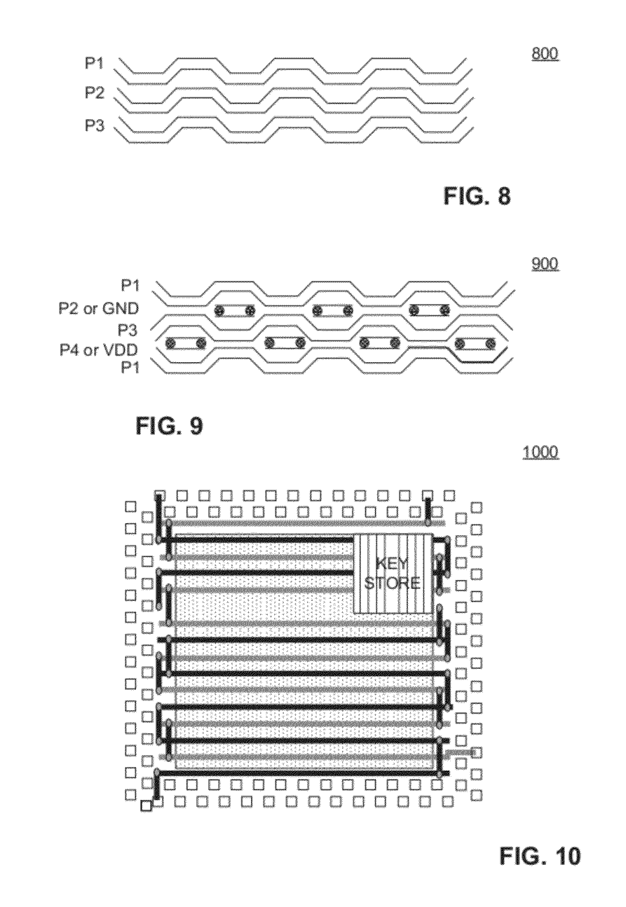

FIG. 8 depicts an exemplary protective mesh pattern 800, according to embodiments of the present invention. Protective mesh pattern 800 uses a zig-zag between opposing polarities. FIG. 9 depicts another exemplary protective mesh pattern 900, according to embodiments of the present invention. This pattern takes advantage of additional polarities to increase the difficulty for a hacker to successful bypass the mesh. Adding an additional layer over the mesh shown in FIG. 9 where P2 and P4 are placed over the minimum spaced P1 and P3 signals and the pattern repeated but offset, further complicates the jumper process for an attacker.

FIG. 10 depicts a single layer protective mesh 1000, according to embodiments of the present invention. Mesh 1000 is implemented in a more complex pattern, making bypass more difficult. In an embodiment, mesh 1000 is built in RDL. In this embodiment, wire pads are connected in layer M6 for driving and detecting the tamper circuit made by the mesh wire. Alternatively, single layer mesh 1000 may be planned by adding a via layer between M6 driver and detection pads, using M7 as the connection layer, and RDL as the mesh.

Additionally, a dual layer mesh can be utilized provided the upper layer mesh protects the lower layer mesh connections. Ideally, the upper layer mesh connections are protected by the lower layer mesh.

### 4.0 Package Level Protection

The bond wire protection described above provides protection against attacks to the package from the sides or at angles. However, an attacker can also attack a package from the top (e.g., to place a tap inside the die). Techniques are required to increase the difficulty of such attacks as well as to detect top attacks and take protective action such as erase sensitive information (e.g., cryptographic key material).

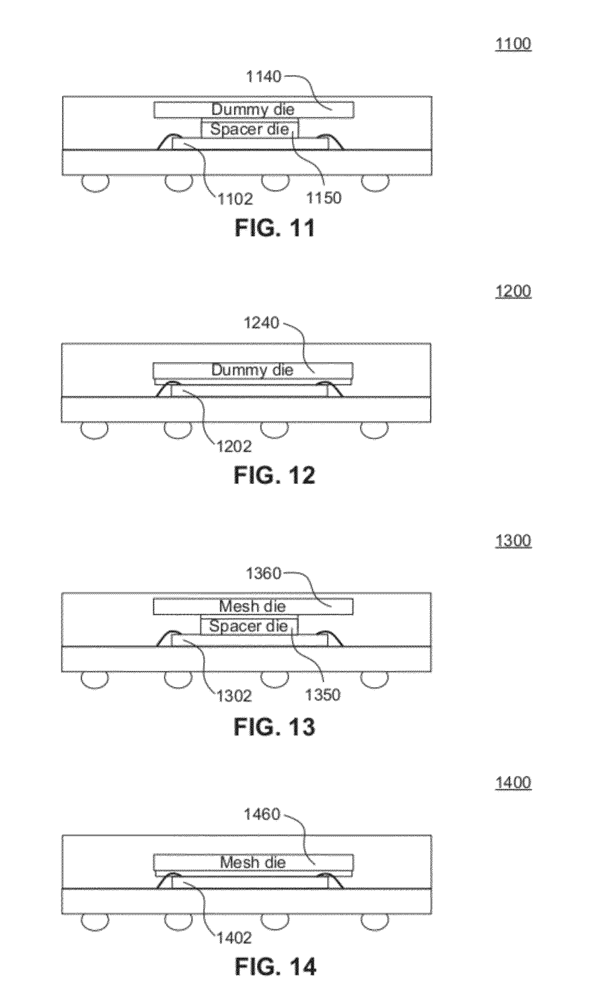

FIGS. 11-16 depict embodiments of package level protection, according to embodiments of the invention. Package level protection can be used in combination with the bond wire protection and/or the die mesh protection described above. Alternatively, package level protection can be used alone. Package level protection can be provided via a stacked die approach (described in Section 4.1) or via a package-on-package approach (described in Section 4.2).

Typically, protection from and detection of top attacks to the package are provide via a mesh grid located on the die. A limitation of these internal die mesh techniques is that mesh grid protection is required to be manufactured in every die, regardless of the needs of the customer. The embodiments depicted in FIGS. 13-16 provide mesh grid protection separate from the die. In these embodiments, the mesh grid protection is provided as part of the package, external to the die.

### 4.1 Stacked Die Approach

FIGS. 11 and 12 depict stacked die embodiments having mechanical only security protection. Package 1100 of FIG. 11 includes a dummy die 1140 having an area equal to or greater than the area of die 1102. Dummy die 1140 is separated from die 1102 by a spacer die 1150. Therefore, to access die 1102, an attacker must physically remove all or a portion of dummy die 1140 and spacer die 1150. Package 1200 of FIG. 12 includes a dummy die 1240 having an area equal to or greater than the area of die 1202. Dummy die 1240 is stacked directly on die 1202. That is, package 1200 does not include a spacer die. The embodiments of FIGS. 11 and 12 provide only physical protection. Therefore, the security features of these packages can be destroyed without detection. These embodiments primarily increase the difficulty of top attacks.

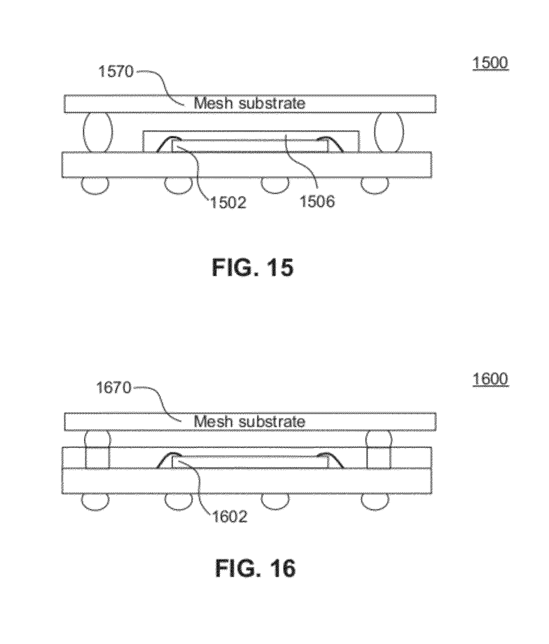

FIGS. 13 and 14 depict stacked die protection embodiments, according to embodiments of the invention. Packages 1300 and 1400 include a mesh die 1360, 1460 having an area equal to or greater than the area of die 1302, 1402. Thus, mesh die 1360, 1460 provides a multi-layer protective mesh over the entire lower die 1302, 1402. In the embodiment of FIG. 13, mesh die 1360 is separated from die 1302 by a spacer die 1350. In the embodiment of FIG. 14, mesh die 1460 is stacked directly on die 1402. In an embodiment, mesh die 1360, 1460 includes a mesh grid. The bond wires 1320, 1420 in packages 1300 and 1400 respectively surround the entire die and provide connection between the substrate and the mesh die. Bond wires 1320, 1420 provide greater protection than a solder ball surround (as described below for FIGS. 15 and 16) because they can be spaced closer together than solder balls.

The stacked die embodiments of FIGS. 13 and 14 provide mesh protection over the entire die using the top mesh die 1360, 1460 as a mesh. In these embodiments, the mesh grid may be driven from the protected lower die 1302, 1402 using an external mesh driving circuit. In embodiments, additional functionality (e.g., memory) may be provided in top mesh die 1360, 1460.

### 4.2 Package on Package Approach

FIGS. 15 and 16 depict exemplary package-on-package approaches, according to embodiments of the present invention. In these embodiments, a mesh substrate having a mesh grid is utilized to protect the die 1502, 1602. In package 1500, die 1502 is surrounded by a ball grid array coupled to mesh substrate 1570. Additionally, die 1502 is encased in an encapsulate 1506. Encapsulate 1506 is also surrounded by the ball grid array. As would be appreciated by persons of skill in the art, a custom mold cap may be required to mold the encapsulate. The height of the balls in the ball grid array must be greater then the height of the encapsulate. Mesh substrate 1570 is stacked on the ball grid array. The mesh substrate 1570 completely covers die 1502.

In package 1600, no custom molded encapsulate is required. Instead, the ball grid array of mesh substrate 1670 is coupled to spacers in the encapsulate layer on lower substrate 1604. In this embodiment, the height of the balls in the ball grid array is not tied to the height of the die or encapsulate.

The package on package embodiments of FIGS. 15 and 16 provide a mesh over the entire die using a top package mesh substrate. Thus, in these embodiments, no extra die is required. In these embodiments, the multi-layer mesh grid may be driven from the protected lower die using an external mesh driving circuit located in the secure area of the die. Connections to the upper mesh substrate are made using the solder balls between the packages. In an embodiment, the solder balls are placed on all four sides of the package with a minimum ball spacing and having alternating polarity. This configuration of solder balls provides additional protection from side attacks. Therefore, the embodiments of FIGS. 15 and 16 may not be used with wire bond protection embodiments described above.

### 5.0 Three-Dimensional Wire-Frame Security Fence

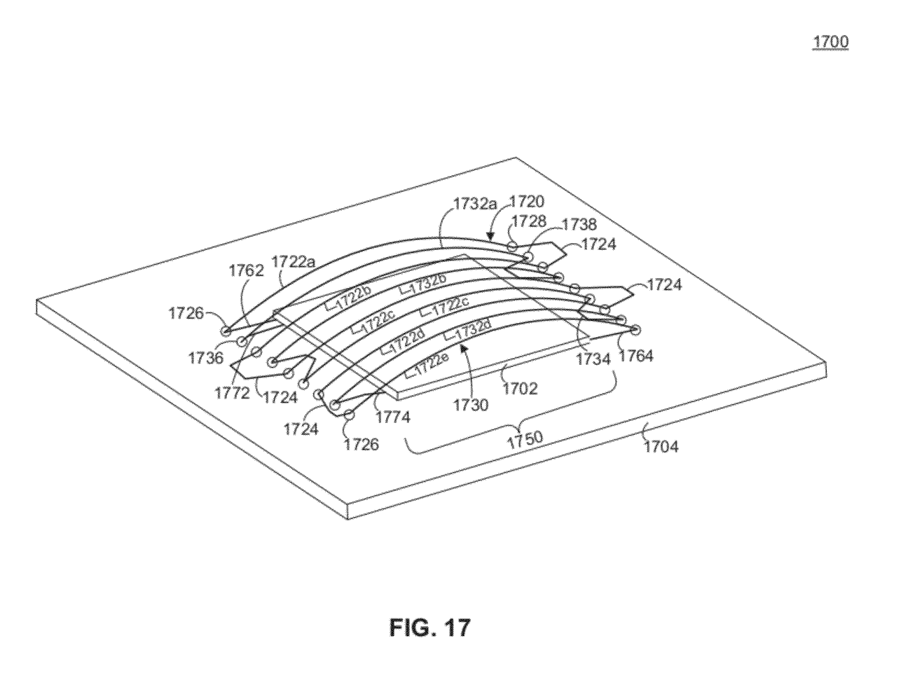

The techniques discussed above for protection against attacks to a chip from the top focused on placing a die or substrate having an internal mesh over the chip to be protected. However, these stacking embodiments may not be feasible in certain applications. FIGS. 17-21 depict an alternate technique for protection of sensitive components from attacks from the top. As described in detail below, in these embodiments, a three-dimensional wire-frame security fence is constructed around the IC chip.

The embodiments of the three-dimensional package security fence disclosed herein can be used in combination with any one of the bond wire protection, the die mesh protection, and/or the package level protection embodiments described above. Alternatively, three-dimensional package security fence protection can be used as a stand-alone physical security protection mechanism.

FIG. 17 depicts a three-dimensional top view of an exemplary package 1700 having a wire-frame security fence, according to embodiments of the present invention. Package 1700 includes a substrate 1704, a chip 1702 coupled to a first surface of substrate 1704, and a security fence 1750 protecting chip 1702. As shown in FIG. 17, chip 1702 is placed between the security fence 1750 and the first surface of the substrate 1704.

A plurality of contacts are disposed on the first surface of the substrate. A first set of contacts 1726 and a second set of contacts 1736 are placed proximate to a first edge of chip 1702. A third set of contacts 1728 and a fourth set of contacts 1738 are placed proximate to a second edge of the chip, opposite the first edge. As illustrated in FIG. 17, contacts 1726 and contacts 1736 are in-line on substrate 1704 proximate to the first edge of chip 1702. Contact 1728 and contacts 1738 are in-line on substrate 1704 proximate to the opposite side of chip 1702.

Security fence 1750 includes two continuous signal nets—net A 1720 and net B 1730. Signal net A 1720 includes a plurality of bonding wires 1722a-d, each bonding wire 1722 extending from a contact 1726 over the top surface of chip 1702 to a contact 1728. A contact in the first set of contacts 1726 is also coupled to a first contact on the die via a connection 1762. In an embodiment, the first contact 1726a is coupled to the die. Additionally, a contact in the third set of contacts 1728 is coupled to the die via a connection 1764. In an embodiment, contact 1728d is coupled to the die. In an embodiment, connections 1762 and 1764 may be trace routing on the top layer of substrate 1704. As would be appreciated by a person of skill in the art, other arrangements for coupling signal net A to the die could be used in the present invention.

Bonding wires 1722a-d are coupled by connections 1724 in a predetermined pattern to form a continuous signal path. As illustrated in FIG. 17, the continuous signal path of signal net A is a zig zag pattern. For example, bonding wire 1722a is coupled to bonding wire 1722b by connection 1724a; bonding wire 1722b is coupled to bonding wire 1722c by connection 1724b; etc. In an embodiment, connections 1724 may be trace routing on the top layer of substrate 1704.

Like signal net A, signal net B 1730 includes a plurality of bonding wires 1732a-d, each bonding wire extending from a contact 1736 over the top surface of chip 1702 to a contact 1738. A contact in the second set of contacts 1736 is coupled to a second contact on the die via a connection 1772 and a second contact in the second set of contacts is coupled to a third contact on the die via a connection 1774. In an embodiment, contact 1736a and 1736d are coupled to the die. In an embodiment, connections 1772 and 1774 may be trace routing on the top layer of substrate 1704. As would be appreciated by a person of skill in the art, other arrangements for coupling signal net B to the die could be used in the present invention.

Bonding wires 1732a-d are coupled by connections 1734 to form a continuous signal path. As illustrated in FIG. 17, the continuous signal path of signal net B is a zig zag pattern. For example, bonding wire 1732a is coupled to bonding wire 1732b by connection 1734a; bonding wire 1732b is coupled to bonding wire 1732c by connection 1734b; etc. In an embodiment, connections 1734 may be trace routing on the top layer of substrate 1704.

Although signal net A and B are depicted as having four bonding wires and four connections, as would be appreciated by a person of skill in the art any number of bonding wires and connections could be used in the security fence. A person of skill in the art would also recognize that a variety of wire materials or wire diameters could be used in the present invention.

As illustrated in FIG. 17, bonding wires 1722 of signal net A 1720 are interleaved with bonding wires 1732 of signal net B 1730. Alternating bonding wires (1722a, 1732a, 1722b, 1732b, etc) are separated by distance x. Distance x is determined such that a probe or similar device cannot be inserted between the alternating bond wires without detection. As would be appreciated by persons of skill in the art, other patterns can be used for the fence. For example, bonding wires 1722 and 1732 may be disposed in a crossed pattern.

As illustrated in FIG. 17, the area of the security fence is determined such that the security fence overlaps the top surface of chip 1702. That is, the length of the security fence from contacts 1726/1736 to contacts 1728/1738 is greater than the length of chip 1702. Similarly, the width of the security (from outer edge of first bonding wire to the outer edge of the last bonding wire) is greater to or at least equal to the width of chip 1702.

In an embodiment, chip 1702 includes tamper detection logic (not shown). As discussed above, signal net A is coupled to chip 1702 via traces 1762 and 1764 and signal net B is coupled to chip 1702 via traces 1772 and 1774. To detect attacks, in an embodiment, tamper detection logic causes a signal to be applied to signal net A. Tamper detection logic may further cause a different signal to be applied to signal net B.

In order to reach the chip, a hacker would need to cut one or more of the bonding wires of signal net A or B or increase the distance between alternating bonding wires, causing the bonding wire of signal net A to touch the bonding wire of signal net B. Cutting one or more of the bonding wires creates an open circuit. Since the bonding wires are not insulated or coated, moving bonding wires until they touch creates a short circuit. The tamper detection logic in chip 1702 is configured to detect an open or short circuit in the security fence. Such a condition is indicative of an attempt to tamper with chip 1702. When tamper detection logic detects a security breach, tamper detection logic may cause chip 1702 to take protective action. For example, tamper detection logic may reset chip 1702 into a dysfunctional mode and/or clear critical data from memory (e.g., erase sensitive data such as key material).

In an additional embodiment, chip 1702 includes logic to configure the electrical connections with security fence 1750 to cause the security fence to act as a Faraday cage. The security fence 1750 can then be used to reduce electromagnetic interference.

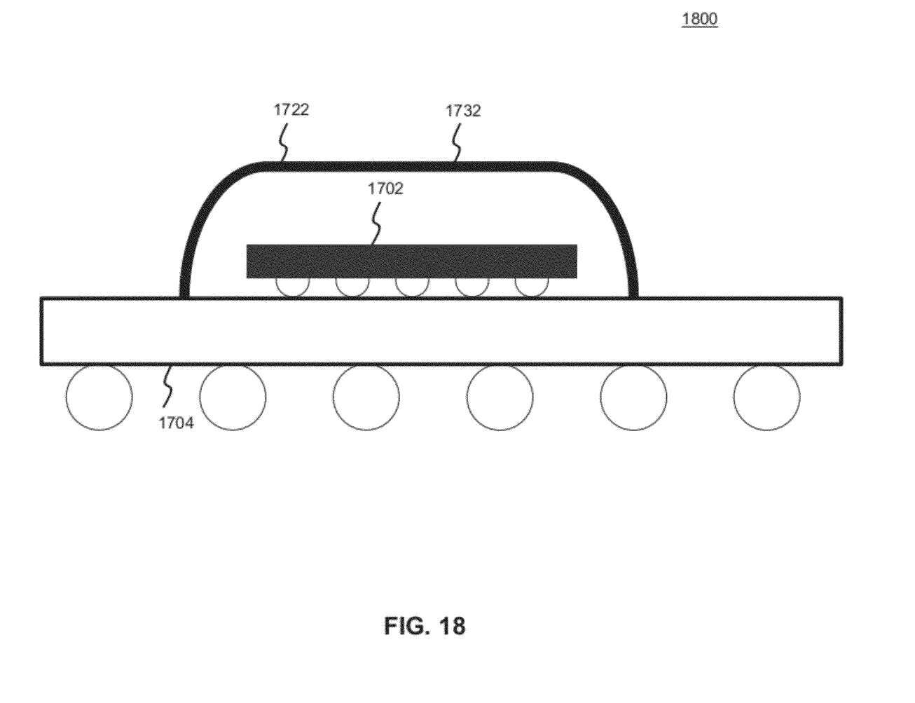

FIG. 18 depicts a cross-section of the exemplary package 1700, according to embodiments of the present invention. As illustrated in FIG. 18, bonding wires 1722 and 1732 create a “cage” or “fence” overlapping the top surface of chip 1702.

Although FIGS. 17 and 18 depict a flip chip package, a person of ordinary skill in the art would appreciate that other types of chip to package interconnects such as wirebond packages could be used with the present invention. Furthermore, a person of skill in the art would recognize that the security fence embodiments disclosed herein are not limited to embodiment within a package. In alternative embodiments, the security fence embodiments can be used in-board (e.g., in wafer level ball grid array (WLBGA on PCB) implementations).

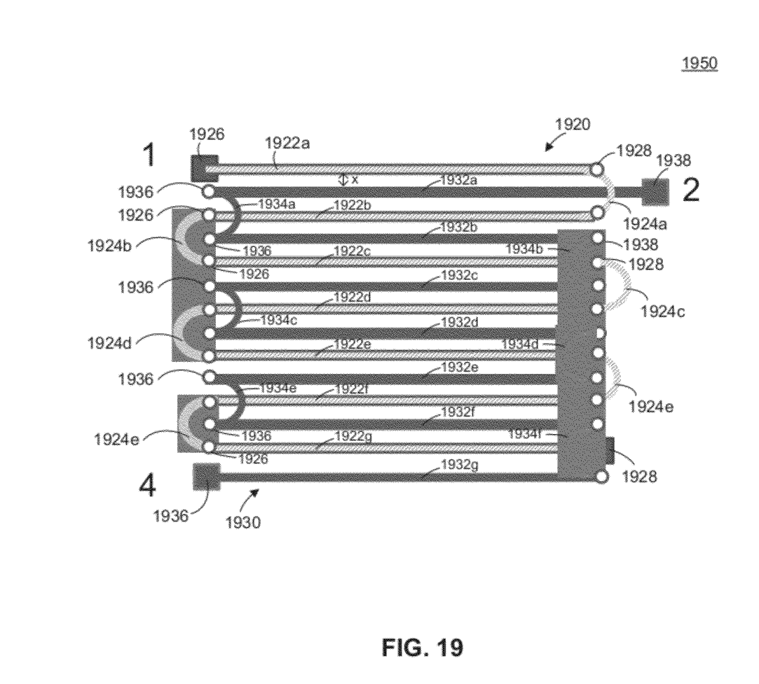

FIG. 19 depicts a top view of an exemplary security fence 1950 having in-line contacts (such as security fence 1750 of FIG. 17), according to embodiments of the present invention. Security fence 1950 includes two continuous signal nets—net A 1920 and net B 1930. Signal net A 1920 includes a plurality of bonding wires 1922a-g, each bonding wire extending from a contact 1926 on a first side of the substrate to a contact 1928 on an opposite side of the substrate. Bonding wires 1922a-g are coupled by connections 1924 in a pre-defined pattern to form a continuous signal path. For example, bonding wire 1922a is coupled to bonding wire 1922b by connection 1924a; bonding wire 1922b is coupled to bonding wire 1922c by connection 1924b; etc. In an embodiment, connections 1924 may be trace routing on the top layer of substrate. Additionally, signal net A may be coupled to one or more contacts on chip 1702 through a set of connections (not shown).

Like signal net A, signal net B 1930 includes a plurality of bonding wires 1932a-g, each bonding wire extending from a contact 1936 on a first side of the substrate to a contact 1938 on the opposite side of the substrate. Bonding wires 1932a-g are coupled by connections 1934 in a predefined pattern to form a continuous signal path. For example, bonding wire 1932a is coupled to bonding wire 1932b by connection 1934a; bonding wire 1932b is coupled to bonding wire 1932c by connection 1934b; etc. In an embodiment, connections 1934 may be trace routing on the top layer of substrate 1904. Signal net B 1930 may also be coupled to one or more contacts on chip 1902 through a set of connections (not shown).

As illustrated in FIG. 19, bonding wires 1922 of signal net A 1920 are interleaved with bonding wires 1932 of signal net B 1930. Alternating bonding wires (1922a, 1932a, 1922b, 1932b, etc.) are separated by distance x. Distance x is determined such that a probe or similar device cannot be inserted between the alternating bond wires without detection. As would be appreciated by persons of skill in the art, other patterns can be used for the fence. For example, bonding wires 1922 and 1932 may be disposed in a crossed pattern.

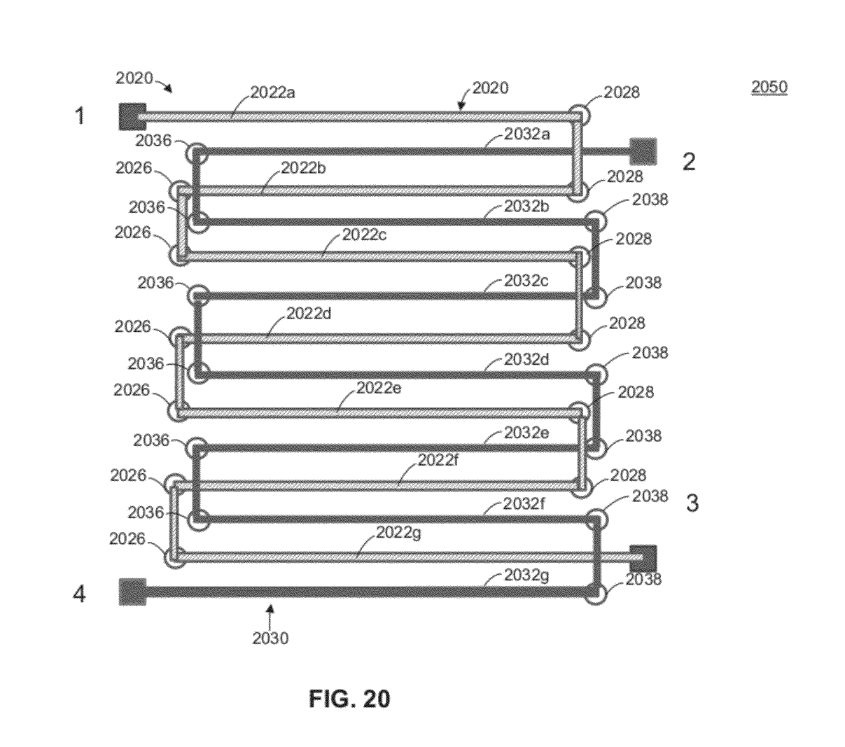

In an alternative embodiment, the substrate contacts for the bonding wires of signal net A are offset from the substrate contacts for the bonding wires of signal net B. FIG. 20 illustrates a top view of an exemplary security fence 2050 having offset substrate contacts, according to embodiments of the present invention.

Security fence 2050 includes two continuous signal nets—net A 2020 and net B 2030. Signal net A 2020 includes a plurality of bonding wires 2022a-g, each bonding wires extending from a contact 2026 on a first side of the substrate to a contact 2028 on an opposite side of the substrate. Like signal net A, signal net B 2030 includes a plurality of bonding wires 2032a-g, each bonding wire extending from a contact 2036 on a first side of the substrate to a contact 2038 on an opposite side of the substrate.

As illustrated in FIG. 20, on the left side of the substrate, contacts for net A (2026) are offset from the substrate contacts for net B (2036) by a distance x. Similarly, on the right side of the substrate, contacts for net A (2028) are offset from the substrate contacts for net B (2038) by a distance y.

Like the embodiment of FIG. 19, the bonding wires of signal net A (1922) are coupled by connections 1924 to form a continuous signal path and the bonding wires of signal net B (1932) are coupled by connections 1934 to form a continuous signal path. Signal net A and signal net B are coupled to the underlying chip via one or more connections. In an embodiment, the security fence 2050 is coupled to a tamper detection circuit in the chip. The functionality of the tamper detection circuit is described above.

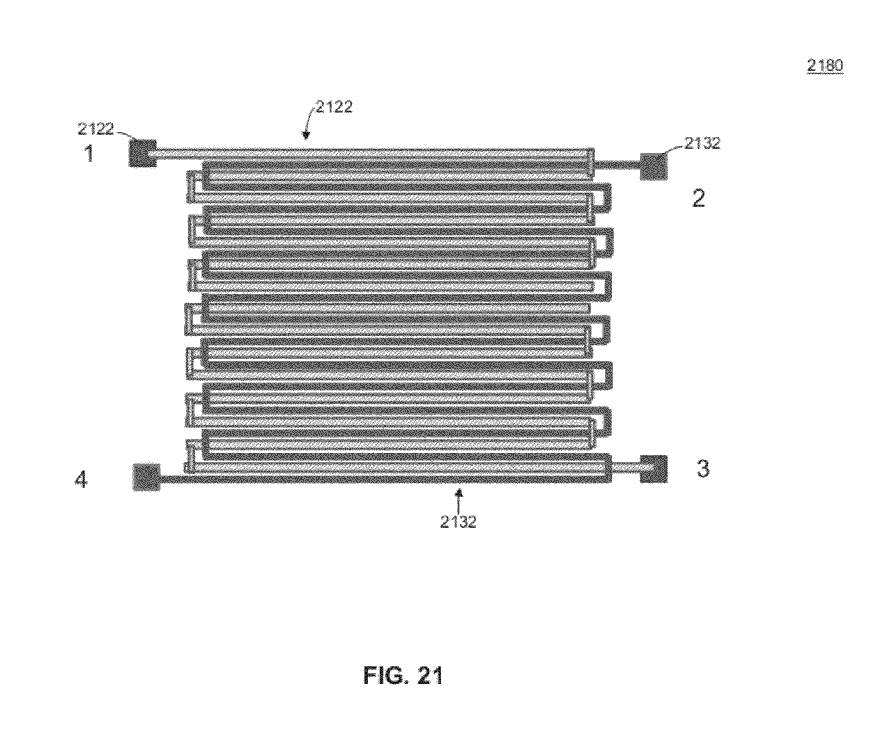

In a further embodiment, the bonding wires are coated or insulated, allowing for higher density of bonding wires to be used to protect the chip. FIG. 21 depicts a top view of an exemplary security fence 2150 having coated or insulated bonding wires, according to embodiments of the present invention. Because the bonding wires are insulated, the bonding wires of signal net A (2122) can be placed close to or touching the bonding wires of signal net B (2132). The insulation of the bonding wires makes the detection of a short impossible. However, the significant decrease in distance between alternating bonding wires makes it extremely difficult for a probe to be used to access the chip without cutting one or more bonding wires. Therefore, in order to access the chip, a hacker must cut one or more of the bonding wires. In this embodiment, a tamper detection circuit in the chip is configured to detect the presence of an open circuit in either signal net A or signal net B.

The security fence of FIG. 21 can have an in-line contacts (as illustrated in FIG. 19) or offset contacts (as illustrated in FIG. 20).

### 6.0 Conclusion

While various embodiments of the present invention have been described above, it should be understood that they have been presented by way of example only, and not limitation. It will be apparent to persons skilled in the relevant art that various changes in form and detail can be made therein without departing from the spirit and scope of the invention. Thus, the breadth and scope of the present invention should not be limited by any of the above-described exemplary embodiments, but should be defined only in accordance with the following claims and their equivalents.

What is claimed is:

1. An integrated circuit package comprising:
a substrate;
a die coupled to a first surface of the substrate; and
a security fence having a first edge and a second edge, wherein the first edge of the security fence is coupled to the first surface of the substrate proximate to a first side of the die and the second edge of the security fence is coupled to the first surface of the substrate proximate to a second side of the die, opposite the first side of the die and wherein the die is between the security fence and the first surface of the substrate, the security fence including:
a plurality of first bonding wires coupled with a plurality of first connections on the first surface of the substrate to form a first continuous signal path, and
a plurality of second bonding wires coupled with a plurality of second connections on the first surface of the substrate to form a second continuous signal path,
wherein the plurality of first bonding wires and plurality of second bonding wires are arranged to form a pattern.

2. The package of claim 1, wherein the plurality of first bonding wires and the plurality of second bonding wires are interleaved.

3. The package of claim 2, wherein the first continuous signal path is connected to a first contact on the die and the first continuous signal path is connected to a second contact on the die.

4. The package of claim 3, wherein the second continuous signal path is connected to a third contact on the die and the second continuous signal path is connected to a fourth contact on the die.

5. The package of claim 4, wherein the die includes a tamper detection circuit.

6. The package of claim 5, wherein the tamper detection circuit causes a first signal to be applied to the first continuous signal path and a second signal to be applied to the second continuous signal path.

7. The package of claim 6, wherein the tamper detection circuit is configured to detect an open circuit in the first continuous signal path.

8. The package of claim 7, wherein the tamper detection circuit is configured to detect an open circuit in the second continuous signal path.

9. The package of claim 6, wherein the tamper detection circuit is configured to detect a short circuit in the security fence.

10. The package of claim 5, wherein the tamper detection circuit is configured to take protective action upon detection of an attempt to access the die through the security fence.

11. The package of claim 1, wherein the security fence is configured to act as a Faraday cage.

12. The package of claim 1, wherein the security fence has a length and a width, wherein the length extends from the first edge of the security fence to a second edge of the security fence and wherein the width of the security fence is greater than the width of the die.

13. The package of claim 12, wherein the length of the security fence is greater than the length of the die.

14. The package of claim 1, wherein the security fence has a length and a width, wherein the length extending from the first edge of the security fence to a second edge of the security fence and wherein the width of the security fence is equal to the width of the die.

15. The package of claim 14, wherein the length of the security fence is greater than the length of the die.

16. The package of claim 1, wherein the first plurality of bonding wires and the second plurality of bonding wires are insulated.

17. The package of claim 16, wherein the first plurality of bonding wires and the second plurality of bonding wires are interleaved such that the adjacent bonding wires touch.

18. An integrated circuit package comprising:
a substrate having a plurality of first contacts, a plurality of second contacts, a plurality of third contacts, and a plurality of fourth contacts, disposed on a first surface of the substrate;
a die coupled to a first surface of the substrate, wherein the plurality of first contacts and second contacts are located on a first side of the die and the plurality of third contacts and fourth contacts are located on a second side of the die, opposite the first side of the die; and
a security fence, wherein the security fence comprises:
a first signal net having:
a plurality of first bonding wires, each bonding wire in the plurality of first bonding wires extending from a contact in the plurality of first contacts over a top surface of the die to a contact in the plurality of third contacts, and
a plurality of first connections coupling the first bonding wires together to form a continuous signal path from a first contact in the plurality of first contacts to a last contact in the plurality of third contacts,
a second signal net having:
a plurality of second bonding wires, each bonding wire in the plurality of second bonding wires extending from a contact in the plurality of second contacts over a top surface of the die to a contact in the plurality of fourth contacts, and
a plurality of second connections coupling the second bonding wires together to form continuous signal path from a first contact in the plurality of third contacts to a last contact in the plurality of fourth contacts,
wherein the plurality of first bonding wires and second bonding wires are disposed to form a pattern.

19. The package of claim 18, wherein the plurality of first contacts and the plurality of second contacts are in-line and the plurality of third contacts and the plurality of fourth contacts are in-line.

20. The package of claim 18, wherein the plurality of first contacts are offset from the plurality of second contacts and the plurality of third contacts are offset from the plurality of fourth contacts.
